(19) United States
(12) Patent Application Publication
(10) Pub. No.: US 2017/0276704 A1
(43) Pub. Date: Sep. 28, 2017

(54) OPTICAL DEVICE PACKAGE AND OPTICAL SWITCH

(71) Applicant: FUJIKURA LTD., Tokyo (JP)

(72) Inventor: Kohei MATSUMARU, Sakura-shi (JP)

(73) Assignee: FUJIKURA LTD., Tokyo (JP)

(21) Appl. No.: 15/508,988

(22) PCT Filed: Mar. 22, 2016
(86) PCT No.: PCT/JP2016/059026

§ 371 Date: Mar. 6, 2017

(30) Foreign Application Priority Data
Jun. 29, 2015 (JP) 2015-130281

(51) Int. Cl. G01R 13/40; G02B 6/35; H05K 5/00; G02F 1/1343

(52) U.S. Cl. CPC G01R 13/40; G02F 1/1343; G02B 6/3518; H05K 5/0095; G02F 1/134309

(57) ABSTRACT

The present invention makes it possible to inhibit decrease in optical performance due to a foreign object, while securing a space necessary for wire bonding. A cover (3) is configured such that a distance (z2) between an optical device (1) and a sub-cover member (32) becomes greater than a distance (z1) between the optical device (1) and a cover glass (31).

### TECHNICAL FIELD

The present invention relates to (i) an optical device package in which an optical device is hermetically sealed and (ii) an optical switch.

### BACKGROUND ART

Conventionally, as a technique to inhibit influence of moisture and the like on an optical device, an optical device package is known in which the optical device is hermetically sealed. Patent Literature 1 discloses a technique relating to such an optical device package.

FIG. 6 is a cross-sectional view schematically illustrating a configuration of the optical device package disclosed in Patent Literature 1. An optical device package 200 illustrated in FIG. 6 includes an optical device 101, a housing 102 having a lateral wall section 103, a bonding wire 104, and a cover glass 105.

The optical device 101 is contained in the housing 102 and an upper surface of the optical device 101 is connected with the housing 102 with the bonding wire 104. The cover glass 105 serves as a cover for closing an opening that is formed by the lateral wall section 103 of the housing 102.

### CITATION LIST

### Patent Literature

[Patent Literature 1]

Japanese Patent Application Publication Tokukai No. 2008-16693 (Publication date: Jan. 24, 2008)

### SUMMARY OF INVENTION

### Technical Problem

In the optical device package 200 illustrated in FIG. 6, a foreign object 106 may intrude into the housing 102 before the opening is closed by the cover glass 105.

Conventionally, in order to prevent the foreign object 106 from intruding into the housing 102, a method has been employed in which the optical device package 200 is produced in a clean room, and the like. However, even by employing such a method, it is difficult to completely prevent the foreign object 106 from intruding into the housing 102.

The optical device package 200 has the following problem. That is, as a space 107 between the optical device 101 and the cover glass 105 becomes larger, the foreign object 106 which has intruded into the housing 102 is more likely to stick to a light receiving section which is provided in the upper surface of the optical device 101 or to float above the light receiving section. From this, in a case where the optical device 101 is an optical switching device, a problem occurs in which crosstalk is caused due to refraction of light by the foreign object 106, and the crosstalk leads to malfunction of the optical device 101 in the optical device package 200. Alternatively, in a case where the optical device 101 is a solid-state image pickup element, a problem occurs in which light is reflected or refracted by the foreign object 106, and therefore an amount of light received by the optical device 101 is remarkably decreased.

Meanwhile, in a case where the space 107 is made smaller in order to solve those problems, a possibility that the cover glass 105 interferes with the bonding wire 104 increases. Alternatively, in a case where the space 107 is not provided by joining the upper surface of the optical device 101 to the cover glass 105 or the like in order to solve those problems, the bonding wire 104 cannot be connected to the optical device 101. Therefore, in the optical device package 200, it is necessary to secure the space 107 which is large to some extent in order to connect the bonding wire 104 to the upper surface of the optical device 101.

The present invention is accomplished in view of the problems, and its object is to provide an optical device package and an optical switch which make it possible to inhibit decrease in optical performance due to a foreign object, while securing a space necessary for wire bonding.

### Solution to Problem

In order to attain the object, an optical device package in accordance with an aspect of the present invention includes: an optical device which has an effective region and a terminal that is juxtaposed to the effective region; a housing in which the optical device is contained; and a cover which is provided for the housing, the cover having a first lid region which faces with the effective region and a second lid region which faces with the terminal, the cover being configured such that a distance between the optical device and the second lid region becomes greater than a distance between the optical device and the first lid region.

According to the configuration, it is possible to make the distance between the optical device and the first lid region smaller. From this, it is possible to inhibit, by the cover, a foreign object which has intruded into the housing from moving toward the effective region provided in an upper surface of the optical device. Further, according to the configuration, the distance between the optical device and the second lid region is greater than the distance between the optical device and the first lid region, and it is therefore possible to leave, between the optical device and the second lid region, a space necessary for wire bonding. That is, according to the configuration, it is possible to inhibit decrease in optical performance due to the foreign object, while securing a space necessary for wire bonding.

### Advantageous Effects of Invention

The present invention makes it possible to inhibit decrease in optical performance due to the foreign object, while securing a space necessary for wire bonding.

### BRIEF DESCRIPTION OF DRAWINGS

FIG. 1 is a perspective view illustrating a configuration of an optical device package in accordance with Embodiment 1 of the present invention.

FIG. 2 is a cross-sectional view illustrating the optical device package taken along the line A-A in FIG. 1.

FIG. 3 is a cross-sectional view illustrating a configuration of an optical device package in accordance with Embodiment 2 of the present invention.

FIG. 4 is a plan view illustrating, in (a) and (b), a configuration of a cover of the optical device package illustrated in FIG. 2 or FIG. 3.

FIG. 5 is a cross-sectional view illustrating a configuration of an optical switch including the optical device package illustrated in FIG. 1.

FIG. 6 is a cross-sectional view schematically illustrating a configuration of an optical device package in accordance with a conventional technique.

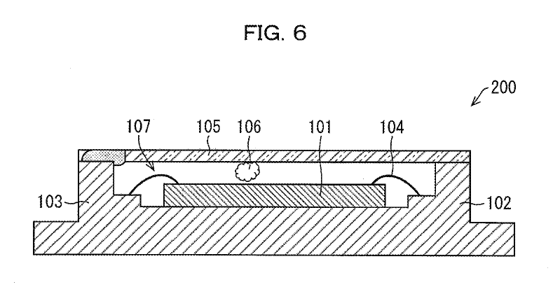

### DESCRIPTION OF EMBODIMENTS

The following description will discuss embodiments of the present invention. Note that, hereinafter, identical reference numerals are given to constituent members having functions identical with those of constituent members described earlier, and descriptions of such constituent members are omitted.

### Embodiment 1

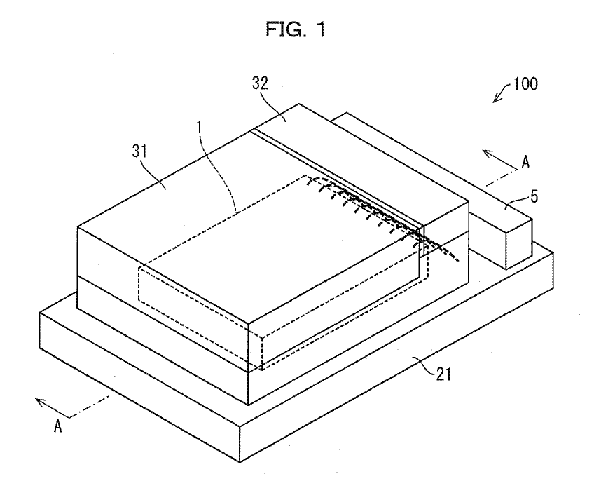

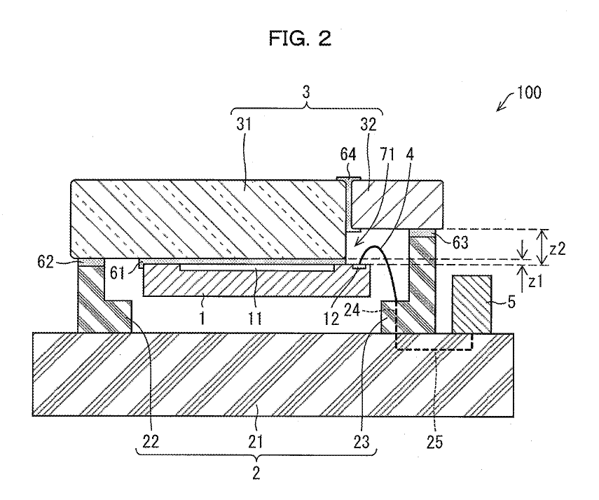

FIG. 1 is a perspective view illustrating an optical device package 100 in accordance with Embodiment 1 of the present invention. Moreover, FIG. 2 is a cross-sectional view illustrating the optical device package 100 taken along the line A-A in FIG. 1.

The optical device package 100 illustrated in FIGS. 1 and 2 includes an optical device 1, a housing 2, a cover 3, a bonding wire 4, and a connector 5.

The optical device 1 has (i) a light receiving section (effective region) 11 that is provided in a surface on a cover 3 side and (ii) a terminal 12 that is juxtaposed to the light receiving section 11. Here, the “effective region” means a region which optically influences light or is optically influenced by light. Examples of the optical device 1 encompass a liquid crystal on silicon (LCOS) element which has a liquid crystal section as the light receiving section 11; a solid-state image pickup element which includes a right-receiving area having a pixel structure as the light receiving section 11; and the like. Note that, in a case where the optical device 1 is a LCOS element, the optical device package 100 can further include a heater or a cooling mechanism for managing a temperature of the LCOS element.

The housing 2 is to contain the optical device 1, and includes a ceramic substrate 21 and sealing frames (i.e., lateral walls of the housing) 22 and 23. The sealing frames 22 and 23 are provided on the ceramic substrate 21 so as to surround the optical device 1, and are made of non-light-transmissive ceramic, metal, or the like. The sealing frame 23 is greater in height than the sealing frame 22. The sealing frame 22 and the sealing frame 23 can be separate members, or one (1) sealing frame can serve as both the sealing frames 22 and 23.

The cover 3 is provided above the optical device 1 and is a cover for the housing 2 (i.e., conformed to the housing 2). The cover 3 has a cover glass (first lid region) 31 and a sub-cover member (second lid region) 32. The cover glass 31 faces with the light receiving section 11 and is made of glass which is a light-transmissive material. The sub-cover member 32 is provided adjacently to the cover glass 31 in a width direction of the cover glass 31 (i.e., a right-and-left direction in FIG. 2), and faces with the terminal 12. The sub-cover member 32 can be made of a material different from glass, and can rather be made of a non-light-transmissive material such as a metal material. In view of inhibiting deterioration of constituent members in the housing 2 by light entered the optical device package 100, the sub-cover member 32 is preferably made of a non-light-transmissive material. Moreover, in view of reducing a stress, the sub-cover member 32 is preferably made of (i) a material having a thermal expansion coefficient that is a middle of a thermal expansion coefficient of the sealing frame 23 and a thermal expansion coefficient of the cover glass 31 or (ii) a resin material which buffers the stress.

One end of the bonding wire 4 is connected with the terminal 12 that is on the surface of the optical device 1 on the cover 3 side. The other end of the bonding wire 4 is connected with the connector 5 via a wire 24 which is provided in the sealing frame 23 and via a wire which is provided in the ceramic substrate 21. With the configuration, in the optical device package 100, the optical device 1 is electrically connected with the connector 5.

The optical device 1 is joined to the cover glass 31 with a joining layer 61. The sealing frame 22 is joined to the cover glass 31 with a joining layer 62. The sealing frame 23 is joined to the sub-cover member 32 with a joining layer 63. The cover glass 31 is joined to the sub-cover member 32 with a joining layer 64. Each of the joining layers 61 through 64 is provided by coating, lamination, or the like, and is preferably made of, for example, epoxy resin which can be hardened at an ordinary temperature. With the configuration, joining of those members can be carried out under a low temperature environment, and this makes it possible to reduce damage by heat with respect to the optical device 1.

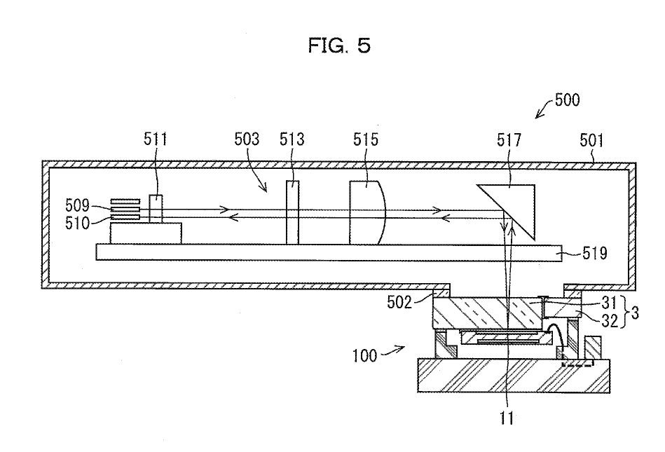

Here, a distance z2 between the optical device 1 and the sub-cover member 32 is greater than a distance z1 between the optical device 1 and the cover glass 31. This makes it possible to inhibit, by the cover 3, a foreign object (see foreign object 106 in FIG. 5) which has intruded into the housing 2 from moving toward the light receiving section 11 of the optical device 1 in the upper surface of the optical device 1. From this, it is possible to prevent the foreign object from sticking to the light receiving section 11 of the optical device 1 or prevent the foreign object from floating above the light receiving section 11, and this makes it possible to inhibit malfunction of the optical device 1 or inhibit decrease in amount of received light. Specifically, in a case where the optical device 1 is an optical switching device, it is possible to inhibit malfunction of the optical device 1. Alternatively, in a case where the optical device 1 is a solid-state image pickup element, it is possible to inhibit decrease in amount of light received by the optical device 1. Furthermore, the distance z2 is greater than the distance z1, and therefore it is possible to leave, between the optical device 1 and the sub-cover member 32, a space 71 which is necessary for wire bonding. That is, it is possible to inhibit decrease in optical performance due to a foreign object, while securing the space 71 which is necessary for wire bonding.

Note that, in the optical device package 100, the terminal 12 is provided so as to be embedded in the optical device 1, and therefore an upper surface of the terminal 12 is flush with an upper surface of the light receiving section 11. Meanwhile, in the optical device package in accordance with an aspect of the present invention, it is possible that the terminal 12 is provided so as to be mounted on the optical device 1 and therefore the upper surface of the terminal 12 is located higher than the upper surface of the light receiving section 11. In such a case also, the distance z2 indicated in FIG. 2 can be a distance between the sub-cover member 32 and the optical device 1 which has a rectangular parallelepiped shape, regardless of the height of the terminal 12. This is because the height of the terminal 12 is sufficiently small to an extent that can be ignored with respect to the distance z2 indicated in FIG. 2.

Moreover, the cover glass 31 and the sub-cover member 32 are separate members. From this, in a state where only the cover glass 31 is provided, an opening is formed above the terminal 12. As a result, it is possible to easily carry out wire bonding with respect to the optical device 1. Moreover, in this case, the light receiving section 11 is covered with the cover glass 31, and it is therefore possible to reduce a possibility that a foreign object sticks to the light receiving section 11 while carrying out the wire bonding.

Moreover, as above described, the optical device 1 is joined to the cover glass 31. From this, the distance z1 becomes substantially zero, and it is therefore possible to further surely prevent a foreign object from sticking to the light receiving section 11 of the optical device 1 or a foreign object from floating above the light receiving section 11. Moreover, after the optical device 1 is joined to the cover glass 31 in the processes of producing the optical device package 100, it is possible to decrease requested cleanliness in a production environment, and it is therefore possible to expect reduction in a cost of producing the optical device package 100. Note that the “substantially zero” indicates that there is a case where the distance z1 is not exactly zero but is approximately zero, as well as a case where the distance z1 is exactly zero. The case where the distance z1 is approximately zero can be a case where the joining layer 61 exists as illustrated in FIG. 1; a case where some sort of space is formed between the optical device 1 and the cover glass 31 which are in a joining state; a case where adhesion between the optical device 1 and the cover glass 31 which are in a joining state is not sufficient; or the like.

Moreover, the cover glass 31 is thicker than the sub-cover member 32. This makes it possible to easily achieve the configuration in which the distance z2 is greater than the distance z1. Note that, further to the above, in the optical device package 100, a surface of the sub-cover member 32 which surface is on an optical device 1 side is higher in location than a surface of the cover glass 31 which surface is on the optical device 1 side. Further, a height of a surface of the sub-cover member 32 which surface is opposite to the optical device 1 is substantially identical with a height of a surface of the cover glass 31 which surface is opposite to the optical device 1.

Note that a method for achieving the configuration in which the distance z2 is greater than the distance z1 is not limited to this. For example, it is possible to employ a method in which the upper surface of the cover glass 31 is located lower than the upper surface of the sub-cover member 32. In this case, it is not essential that the cover glass 31 is thicker than the sub-cover member 32.

Moreover, by providing the bonding wire 4 in the space 71, it is possible to inexpensively and easily establish electrical connection in the optical device 1. Further, this makes it possible to bring about the effect of the optical device package 100 while preventing the cover 3 from interfering with the bonding wire 4. Needless to say, in this case, a height of the bonding wire 4 from the surface of the optical device 1 on the cover 3 side is equal to or less than the distance z2.

(Additional Remarks)

Note that the cover in accordance with Embodiment 1 can be a so-called single cover in which the first lid region and the second lid region are integrated. Alternatively, it is possible that the first lid region and the second lid region are made of the same material and are integrated.

Moreover, it is not essential that the optical device in accordance with Embodiment 1 is joined to the first lid region.

In Embodiment 1, the electrical connection in the optical device is established by the wire bonding method with use of the bonding wire. Note, however, that Embodiment 1 is not limited to this. Besides the wire bonding method, stud bump bonding and the like can be employed as the method for establishing electrical connection in the optical device. In the stud bump bonding, a chip pad, a bump, a flexible printed circuit (FPC), a connector or a bump, and a housing pad are provided in this order.

### Embodiment 2

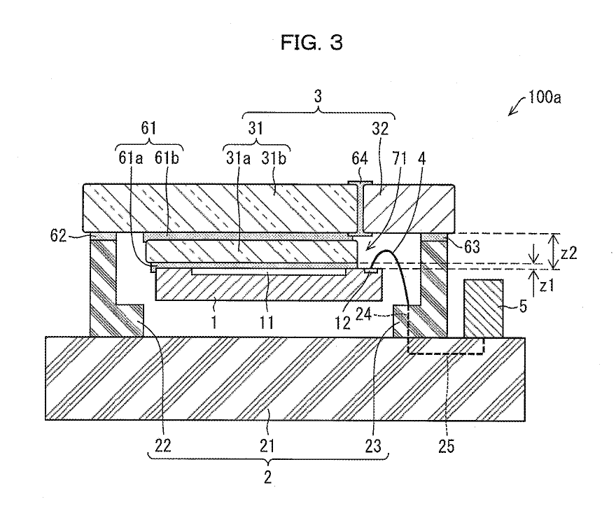

FIG. 3 is a cross-sectional view illustrating an optical device package 100a in accordance with Embodiment 2 of the present invention. A configuration of the optical device package 100a illustrated in FIG. 3 is different from that of the optical device package 100 illustrated in FIG. 2 in the following points.

That is, a cover glass 31 of the optical device package 100a includes two (plurality of) glass plates (layers) 31a and 31b. Each of the glass plates 31a and 31b can be made of a material identical with that of the cover glass 31. In accordance with this configuration, a joining layer 61 also includes (i) a joining layer 61a for joining the optical device 1 to the glass plate 31a and (ii) a joining layer 61b for joining the glass plate 31a to the glass plate 31b. Each of the joining layer 61a and 61b can be made of a material identical with that of the joining layer 61. Moreover, a sealing frame 22 is joined to the glass plate 31b with a joining layer 62. Further, the glass plate 31b is joined to a sub-cover member 32 with a joining layer 64. Meanwhile, the glass plate 31a is not joined to the sealing frame 22 and the sub-cover member 32.

In the optical device package 100a, a thickness of the glass plate (uppermost layer) 31b is identical with that of the sub-cover member 32. Further, the glass plate 31b and the sub-cover member 32 are joined to the respective sealing frames 22 and 23.

This makes it possible to uniformize a height of a lateral wall (i.e., a combination of the sealing frames 22 and 23) of the housing, and therefore a shape of the lateral wall of the housing can be simplified. As a result, it becomes easy to configure the lateral wall of the housing as one (1) member.

Of course, the cover glass 31 can be made up of three or more glass plates (layers).

[Configuration of Cover]

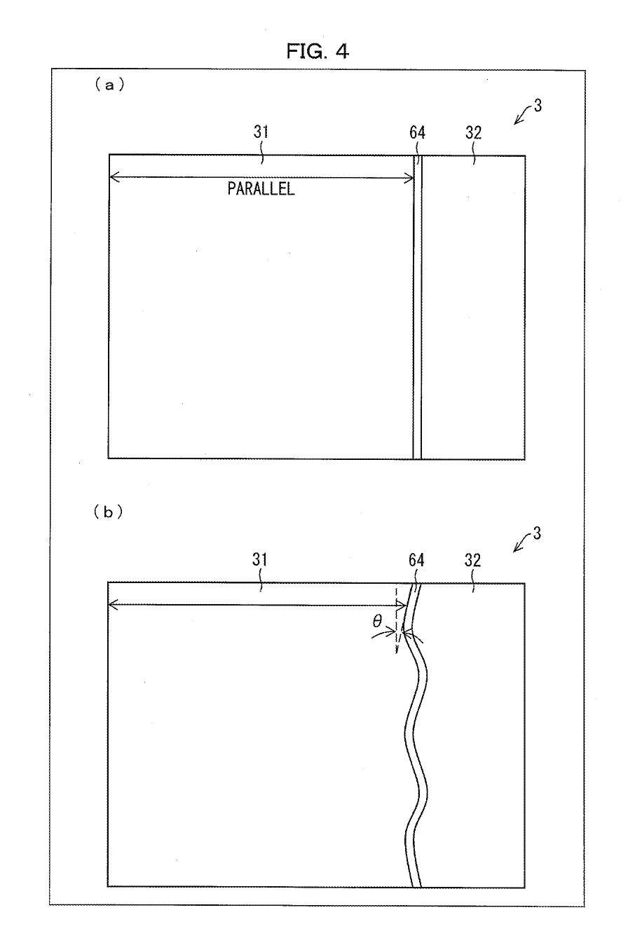

Each of (a) and (b) of FIG. 4 is a plan view illustrating a configuration of the cover 3 of the optical device package 100 illustrated in FIG. 2 or of the optical device package 100a illustrated in FIG. 3.

As illustrated in (a) of FIG. 4, a part of the cover 3 in which part the cover glass 31 is joined to the sub-cover member 32, in other words, a part of the cover 3 in which part the joining layer 64 is provided can extend straight in a top view of the cover 3.

Meanwhile, as illustrated in (b) of FIG. 4, a part of the cover 3 in which part the cover glass 31 is joined to the sub-cover member 32 can meander (i.e., not straight) in the top view of the cover 3. Alternatively, instead of meandering, the part can extend in a zigzag manner or in a comb-like shape. With the configuration, it is possible to increase a joining region between the cover glass 31 and the sub-cover member 32, and therefore the cover glass 31 can be joined to the sub-cover member 32 more firmly.

With reference to (a) and (b) of FIG. 4, the joining part between the cover glass 31 and the sub-cover member 32 is thus described. The same applies to a joining part between the glass plate 31b and the sub-cover member 32 illustrated in FIG. 3.

[Optical Switch]

The following description will discuss, with reference to FIG. 5, an optical switch including the optical device package in accordance with each of the embodiments of the present invention. FIG. 5 is a cross-sectional view illustrating a configuration of an optical switch 500. The optical switch 500 includes the optical device package 100 (see FIGS. 1 and 2). Note, however, that the optical switch 500 can be configured to include the optical device package 100a (see FIG. 3), instead of the optical device package 100.

As illustrated in FIG. 5, the optical switch 500 includes a case 501, an optical system 503 that is provided in the case 501, and the optical device package 100. First, a configuration of the case 501 and an aspect of joining the case 501 to the optical device package 100 will be described, and then a configuration of the optical system 503 will be described.

(Case 501 and Optical Device Package 100)

The case 501 is a case for containing the optical system 503 therein. The case 501 has an opening through which the optical system 503 and the optical device package 100 are optically coupled. A material of the case 501 is not particularly limited and can be, for example, metal, resin, or the like.

The optical device package 100 is joined to the case 501 via a joining member such that the cover 3 overlaps with the opening of the case 501 and the light entrance surface of the cover 3 lies in parallel with a surface of the case 501 which surface surrounds the opening. In the present embodiment, the cover 3 is adhered to the case 501 via an adhesive agent layer 502 which is the joining member. According to the configuration, the light entrance surface of the cover 3 is kept, by the adhesive agent layer 502, parallel to the surface of the case 501 which surface surrounds the opening.

Alternatively, in another example for joining the optical device package 100 to the case 501, the cover 3 can be joined to the case 501 with use of a bolt which is the joining member. A spacer (not illustrated in FIG. 5) for keeping the cover 3 and case 501 parallel to each other is provided between the cover 3 and the case 501.

As such, in the optical switch 500, the surface of the cover 3 is employed as a reference surface for joining the optical device package 100 to the case 501. According to the configuration, it is easy to keep the light receiving surface of the optical device 1 parallel to the case 501. From this, even in a case where a location changes at which light enters the light receiving surface of the optical device 1, it is possible to bring about an effect of easily inhibiting unevenness in light path length.

(Optical System 503)

Next, the following description will discuss the optical system 503 which is contained inside the case 501. The optical system 503 includes an input port 509, output ports 510, a microlens array 511, a dispersing section 513, a light collecting device 515, a mirror 517, and an optical base 519. The input port 509, the output ports 510, the microlens array 511, the dispersing section 513, the light collecting device 515, and the mirror 517 are each fixed on the optical base 519 which is made of light-transmissive glass.

The input port 509 is a port through which light subjected to wavelength-division multiplexing is inputted as input light to the optical switch 500. The output ports 510 are each a port through which output light whose path has been switched by the optical device 1 of the optical device package 100 is outputted from the optical switch 500. The input port 509 and the output ports 510 are each constituted by an optical fiber.

In the optical switch 500, a port array is constituted by at least one input port 509 and a plurality of output ports 510 in combination. Note that FIG. 5 illustrates only one input port 509 and two output ports 510 of the port array thus configured.

The microlens array 511 is configured such that microlenses corresponding to the respective input port 509 and output ports 510 which constitute the port array are arranged in an array. The microlens array 511 (i) converts, into parallel light flux, the input light inputted to the optical switch 500 through the input port 509 and (ii) converges, onto the output port 510, the output light whose path has been switched by the optical device 1.

The dispersing section 513 is for causing the input light, which has been converted into the parallel light flux by the microlens array 511, to be dispersed into light beams according to wavelengths. The dispersing section 513 can be a transmissive dispersion device, or a reflective diffraction grating. In a case where the reflective diffraction grating is employed as the dispersing section 513, a configuration of the optical system 503 can be modified so as to be suitable for the reflective diffraction grating.

The light collecting device 515 collects the light beams, into which the incident light has been dispersed by the dispersing section 513 according to wavelengths. For example, the light collecting device 515 can be a convex lens.

The mirror 517 (i) guides, towards the optical device 1 of the optical device package 100, the input light which has been collected by the light collecting device 515 and (ii) guides, towards the output ports 510, the output light whose path has been switched by the optical device 1.

The input light enters the optical device 1 of the optical device package 100 from the optical system 503 thus configured. The optical device 1 (i) controls alignment of a liquid crystal layer so as to switch a light path of the input light inputted from the optical system 503 and (ii) reflects the input light so as to output thus reflected light to the optical system 503 as the output light.

The optical switch 500 thus configured (i) causes input light inputted through the input port 509 to be dispersed according to wavelengths and (ii) switches a light path of a light beam having a desired wavelength, so that the optical switch 500 can output, as output light to any of the output ports 510, the light beam having a desired wavelength.

[Main Points]

The present invention can also be interpreted as follows.

The optical device package in accordance with an aspect of the present invention includes: an optical device which has an effective region and a terminal that is juxtaposed to the effective region; a housing in which the optical device is contained; and a cover which is provided for the housing, the cover having a first lid region which faces with the effective region and a second lid region which faces with the terminal, the cover being configured such that a distance between the optical device and the second lid region becomes greater than a distance between the optical device and the first lid region.

According to the configuration, it is possible to make the distance between the optical device and the first lid region smaller. From this, it is possible to inhibit, by the cover, a foreign object which has intruded into the housing from moving toward the effective region provided in an upper surface of the optical device. Further, according to the configuration, the distance between the optical device and the second lid region is greater than the distance between the optical device and the first lid region, and it is therefore possible to leave, between the optical device and the second lid region, a space necessary for wire bonding. That is, according to the configuration, it is possible to inhibit decrease in optical performance due to the foreign object, while securing a space necessary for wire bonding.

In the optical device package in accordance with an aspect of the present invention, the first lid region and the second lid region are separate members.

According to the configuration, in a state where only the first lid region is provided, an opening is formed above the terminal of the optical device. As a result, it is possible to easily carry out wire bonding with respect to the optical device. Moreover, in this case, the effective region of the optical device is covered with the first lid region, and it is therefore possible to reduce a possibility that a foreign object sticks to the effective region while providing the wire bonding.

In the optical device package in accordance with an aspect of the present invention, the first lid region is joined to the second lid region; and a part in which the first lid region is joined to the second lid region is not straight in a top view of the cover.

According to the configuration, it is possible to increase a joining region between the first lid region and the second lid region, and therefore the first lid region can be joined to the second lid region more firmly.

In the optical device package in accordance with an aspect of the present invention, the optical device is joined to the first lid region.

According to the configuration, a distance between the optical device and the first lid region becomes substantially zero, and it is therefore possible to further surely prevent a foreign object from sticking to the effective region of the optical device or a foreign object from floating above the effective region. Moreover, after the optical device is joined to the first lid region in the processes of producing the optical device package, it is possible to decrease requested cleanliness in a production environment, and it is therefore possible to expect reduction in a cost of producing the optical device package.

In the optical device package in accordance with an aspect of the present invention, the first lid region is thicker than the second lid region.

According to the configuration, it is possible to easily achieve the configuration in which the distance between the optical device and the second lid region is greater than the distance between the optical device and the first lid region.

In the optical device package in accordance with an aspect of the present invention, the first lid region is made up of a plurality of layers; a thickness of an uppermost layer of the plurality of layers is identical with a thickness of the second lid region; and the uppermost layer and the second lid region are joined to a lateral wall of the housing.

According to the configuration, it is possible to uniformize a height of a lateral wall of the housing, and therefore a shape of the lateral wall of the housing can be simplified. As a result, it becomes easy to configure the lateral wall of the housing as one (1) member.

The optical device package in accordance with an aspect of the present invention includes a bonding wire which is provided in a space between the optical device and the second lid region.

According to the configuration, it is possible to inexpensively and easily establish electrical connection in the optical device. Further, by providing the bonding wire in the space between the optical device and the second lid region, it is possible to bring about the effect of the present invention while preventing the cover from interfering with the bonding wire.

The optical switch in accordance with an aspect of the present invention includes the optical device package in accordance with an aspect of the present invention.

According to the configuration, it is possible to provide the optical switch which can bring about an effect similar to that of the optical device package in accordance with an aspect of the present invention.

The present invention is not limited to the embodiments, but can be altered by a skilled person in the art within the scope of the claims. An embodiment derived from a proper combination of technical means each disclosed in a different embodiment is also encompassed in the technical scope of the present invention.

### INDUSTRIAL APPLICABILITY

The present invention can be used in an optical device package in which an optical device is hermetically sealed.

### REFERENCE SIGNS LIST

1: Optical device
2: Housing
3: Cover
4: Bonding wire
11: Light receiving section (effective region)
12: Terminal
22 and 23: Sealing frame (lateral wall of housing)
31: Cover glass (first lid region)
31a and 31b: Glass plate (layer)
32: Sub-cover member (second lid region)
100 and 100a: Optical device package
z1: Distance between optical device and first lid region
z2: Distance between optical device and second lid region

1. An optical device package comprising:
an optical device which has an effective region and a terminal that is juxtaposed to the effective region;
a housing in which the optical device is contained; and
a cover which is provided for the housing, the cover having a first lid region which faces with the effective region and a second lid region which faces with the terminal,
the cover being configured such that a distance between the optical device and the second lid region becomes greater than a distance between the optical device and the first lid region.

2. The optical device package as set forth in claim 1, wherein:
the first lid region and the second lid region are separate members.

3. The optical device package as set forth in claim 2, wherein:
the first lid region is joined to the second lid region; and
a part in which the first lid region is joined to the second lid region is not straight in a top view of the cover.

4. The optical device package as set forth in claim 1, wherein:
the optical device is joined to the first lid region.

5. The optical device package as set forth in claim 1, wherein:
the first lid region is thicker than the second lid region.

6. The optical device package as set forth in claim 5, wherein:
the first lid region is made up of a plurality of layers;
a thickness of an uppermost layer of the plurality of layers is identical with a thickness of the second lid region; and
the uppermost layer and the second lid region are joined to a lateral wall of the housing.

7. The optical device package as set forth in claim 1, further comprising:
a bonding wire which is provided in a space between the optical device and the second lid region.

8. An optical switch comprising an optical device package recited in claim 1.
